(19) United States
(12) Patent Application Publication
(10) Pub. No.: US 2015/0270138 A1
(43) Pub. Date: Sep. 24, 2015

(54) METHOD FOR FORMING FINE PATTERNS OF SEMICONDUCTOR DEVICE

(71) Applicant: SK HYNIX INC., Icheon (KR)

(72) Inventor: Kwanghee CHO, Icheon (KR)

(21) Appl. No.: 14/317,511

(22) Filed: Jun. 27, 2014

(30) Foreign Application Priority Data
Mar. 19, 2014 (KR) 10-2014-0032108

(51) Int. Cl. H01L 21/311

(52) U.S. Cl. CPC H01L 21/31111; H01L 21/31144

(57) ABSTRACT

A method for forming fine patterns includes: forming a sacrificial layer over an etch target layer; forming a plurality of sacrificial patterns each of which has at least one tapered point at each end of each sacrificial pattern by selectively etching the sacrificial layer; forming spacers at sides of each of the sacrificial patterns; removing the sacrificial layer; and forming the fine patterns by using the spacers as etch barriers and etching the etch target layer.

### CROSS-REFERENCE TO RELATED APPLICATIONS

The present application claims priority of Korean Patent Application No. 10-2014-0032108, filed on Mar. 19, 2014, which is incorporated herein by reference in its entirety.

### BACKGROUND

1. Field

Embodiments of the present disclosure relate to a semiconductor designing technology, and more particularly, to a method for forming fine patterns.

2. Description of the Related Art

As the semiconductor industry advances and users demand more features, electronic devices are becoming smaller in size and lighter in weight to meet demand. To facilitate these advances, semiconductor devices are becoming more integrated. As design rules are scaled down due to the high integration of semiconductor devices, semiconductor devices are requiring finer patterns. Formation techniques involve a photolithography process using a photomask. However, conventional photolithography processes are limited in forming fine patterns due to optical characteristics.

### SUMMARY

An embodiment of the present disclosure is directed to a method for forming fine patterns through a simple pattern forming process.

In accordance with an embodiment of the present invention, a method for forming fine patterns includes: forming a sacrificial layer over an etch target layer; forming a plurality of sacrificial patterns each of which has at least one tapered point at each end on both sides of each sacrificial pattern by selectively etching the sacrificial layer; forming spacers on sidewalls of each of the sacrificial patterns; removing the sacrificial layer including the sacrificial patterns; and forming the fine patterns by using the spacers as etch barriers and etching the etch target layer.

In accordance with another embodiment of the present invention, a method for forming fine patterns includes: forming a second etch target layer over a first etch target layer; forming a plurality of first sacrificial patterns each of which has at least one tapered point at each end on both sides of each first sacrificial pattern over the second etch target layer; forming first spacers on sidewalls of each of the first sacrificial patterns; forming first patterns by using the first spacers as etch barriers and etching the second etch target layer; forming a plurality of second sacrificial patterns each of which has at least one tapered point at each end on both sides of each second sacrificial pattern and crosses the first sacrificial patterns over the first etch target layer; forming second spacers on sidewalls of each of the second sacrificial patterns; and forming second patterns by using the second spacers and the first patterns as etch barriers and etching the first etch target layer.

### BRIEF DESCRIPTION OF THE DRAWINGS

FIGS. 1A to 1H illustrate a method for forming fine line patterns in accordance with a first embodiment.

FIGS. 2A to 2H illustrate a method for forming fine line patterns in accordance with a second embodiment.

FIGS. 3A to 3J illustrate a method for forming fine hole patterns in accordance with an embodiment.

### DETAILED DESCRIPTION

Embodiments will be described below in more detail with reference to the accompanying drawings. Aspects of this disclosure may, however, be embodied in different forms and should not be construed as being limited to the embodiments set forth herein. Rather, these specific embodiments are provided so that this disclosure will be thorough and complete, and will fully convey the scope of the present claims to those skilled in the art. Throughout the disclosure, like reference numerals refer to like parts throughout the various figures and embodiments.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

As semiconductor device design rules are scaled down, it is not possible to form a line and space pattern of 38 nm or less based on half pitch through a typical one-time light exposure due to the limitation of ArF immersion exposure equipment under Numerical Aperture (NA) 1.35. When using extreme ultra violet rays (EUV), a device of half-pitch-based 30 nm or less may be developed when a light source of approximately 13.4 nm is used. However, it is difficult to adopt the EUV process to a production process due to insufficient light source power, instrumental limitations, and immature reticle and resist. To overcome these limitations, a method of forming fine patterns by improving a fabrication process, which is a Spacer Patterning Technology (SPT) is introduced.

The following embodiments are directed to a method for forming fine patterns, and more specifically, to a method for forming fine patterns through a process that is more simplified than a conventional process and uses spacer patterning technology. Conventional spacer patterning technology requires an etch process using a cut mask to divide the spacers formed on the sidewalls of a sacrificial pattern into a plurality of pieces. The following embodiments, however, provide a method for forming fine patterns that may divide the spacers formed on the sidewalls of a sacrificial pattern into a plurality of pieces without using a cut mask. Hereafter, a method for forming a line and space pattern is described.

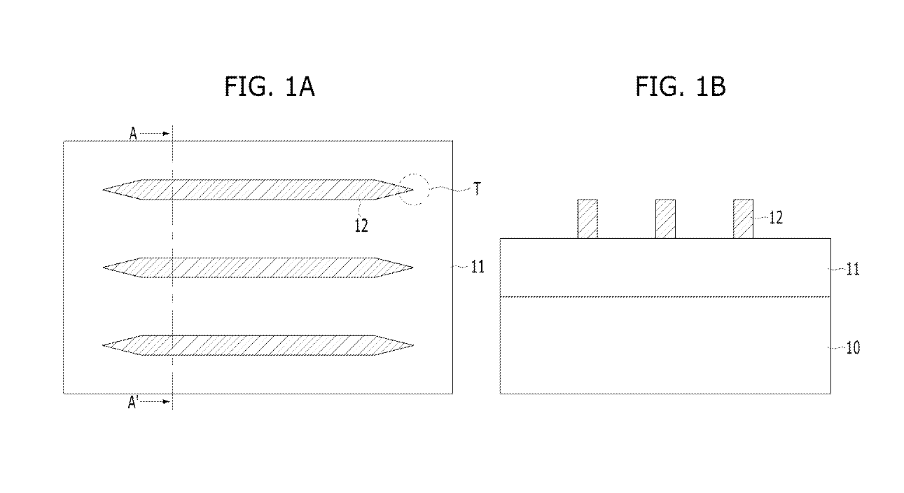

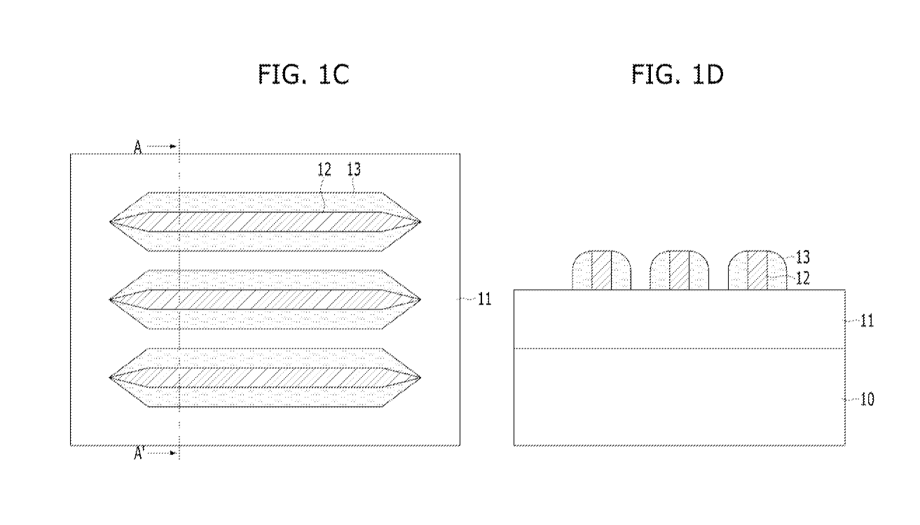

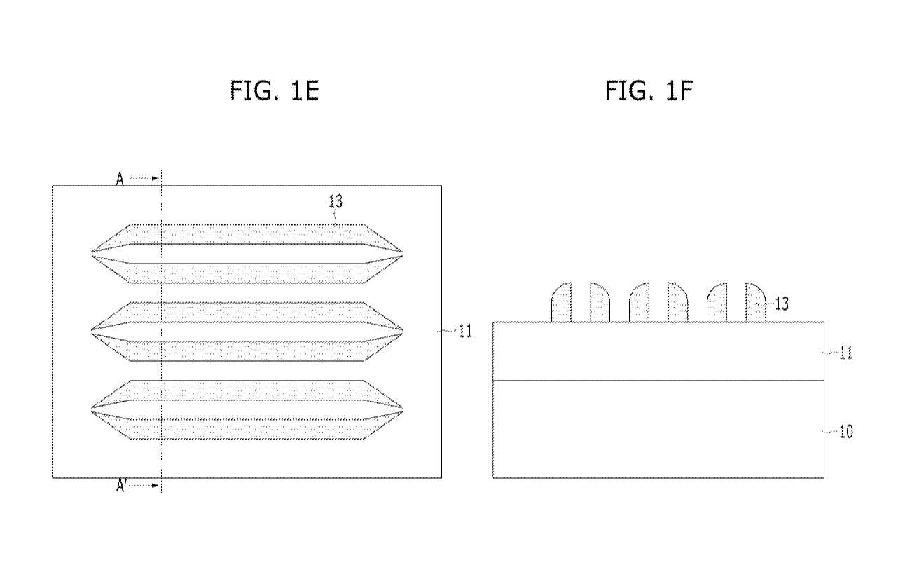

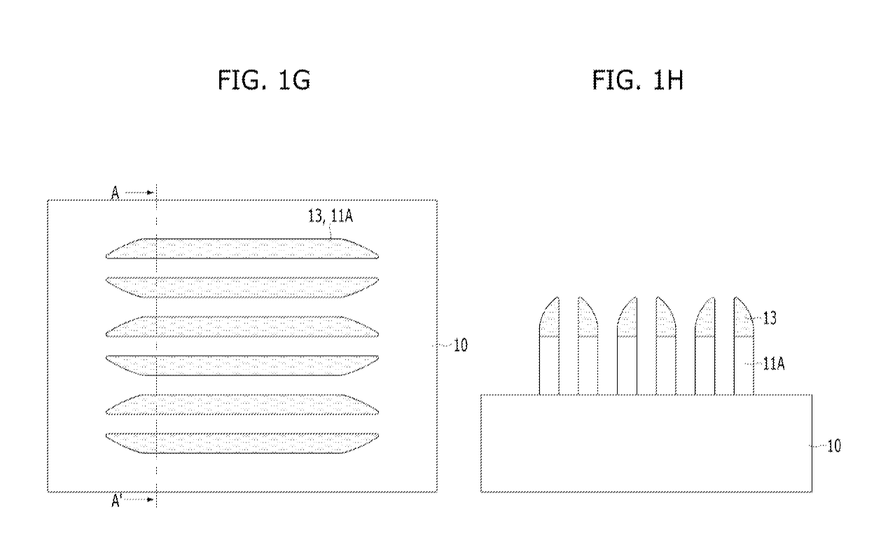

FIGS. 1A to 1H illustrate a method for forming fine line patterns in accordance with a first embodiment. FIGS. 1A, 1C, 1E and 1G are plan views, and FIGS. 1B, 1D, 1F and 1H are cross-sectional views taken along lines A-A′ of the plan views.

Referring to FIGS. 1A and 1B, an etch target layer 11 is formed over a substrate 10, and a sacrificial layer (not shown) is formed over the etch target layer 11. The etch target layer 11 and the sacrificial layer (not shown) may include various materials that are known to those skilled in the art.

Subsequently, a plurality of sacrificial patterns 12, each of which has at least one tapered point T at each end, are formed by selectively etching the sacrificial layer. The sacrificial patterns 12 may be embossed patterns. The embossed sacrificial patterns 12 may have the tapered points T at the ends of each sacrificial pattern protrude outward from of the sacrificial patterns 12. The sacrificial patterns 12 may be elongated or line patterns, and the tapered points T are located at both opposing far ends of the length dimension of the patterns. The sacrificial patterns 12 may be formed in a line and space shape, and the line width of the lines may be longer than the line width of spacers 13 formed in a subsequent process.

Referring to FIGS. 1C and 1D, spacers 13 are formed at sides of each of the sacrificial patterns 12. More specifically, the spacers 13 are formed over sidewalls of the sacrificial patterns 12. The spacers 13 may be formed of a material having an etch selectivity with respect to the etch target layer 11.

The spacers 13 may be formed through a series of processes of depositing a predetermined thickness of a material layer over the profile of a substrate structure including the sacrificial patterns 12, and then performing a blanket etch process, e.g., an etch-back process. Herein, when the material layer is formed over the profile of a substrate structure including the sacrificial patterns 12, the material layer is deposited relatively thin, or lightly deposited, at the ends of the sacrificial patterns 12 due to the presence of the tapered points T. As a result, the spacers 13 may have a in which the line width decreases as it approaches the ends on both sides of each spacer 13. Also, in some embodiments the spacers 13 disposed adjacent to each other at each tapered point T of the sacrificial patterns 12 may be connected in a relatively thin line width or separated from each other. In other words, the tapered ends of the spacers may merge together or be separated by a space.

Referring to FIGS. 1E and 1F, the sacrificial patterns 12 are removed. The sacrificial patterns 12 may be removed through a dry etch process or a wet etch process. As a result of the etch process, portions of the ends of each sacrificial pattern 12 having a relatively thin line width may be partially removed. The partial removal may separate the pairs of spacers 13 of each pattern 12 from each other at the ends of the pattern. In addition, as seen in FIG. 1E, the tapered points of each pair of spacers 13 may be pointed inwards towards one another as a result of the removed tapered point T of the sacrificial pattern 12.

Although not illustrated in the drawing, when the sacrificial patterns 12 are removed, the sacrificial layer remaining over the etch target layer 11 may be removed together.

Referring to FIGS. 1G and 1H, a plurality of patterns 11A are formed by using the spacers 13 as etch barriers and etching the etch target layer 11. The patterns 11A may be formed through a dry etch process. The patterns 11A may be line and space patterns, and the line width of the lines may be the same as the line width of the spaces between the lines.

A characteristic of an etch process is that it may remove more material from thin sections of etched structures than thick sections of the etched structures. Thus, when the patterns 11A are formed, more material may be removed from the relatively thin ends of the spacers 13 than the relatively thick middle portions of the spacers. As a result, portions of adjacent pairs of spacers 13 disposed at the ends of each pattern 11A may be separated from each other. Also, the shape of the spacers 13, which are the etch barriers, is transferred to the patterns 11A, and the ends of the patterns 11A may have a tapered line width that gradually decreases as towards the far ends. In an embodiment, the ends of the patterns 11A may have the line width that gradually decreases in such a manner that an end portion of one sidewall of each end approaches the opposite sidewall at an angle. In other words, as seen in FIG. 1G, inner sidewalls of adjacent pairs of spacers 13 and patterns 11A may be substantially straight and parallel to one another, while outer sidewalls of each pair have a central portion that is substantially straight and parallel to the inner sidewall, and end portions that angle inwards to meet the inner sidewalls at both ends.

According to the embodiment described above with respect to FIGS. 1A-1H, a plurality of fine patterns, each of which is divided into two pieces at the ends of each fine pattern, may be formed by forming the sacrificial patterns 23 having at least one tapered point T at each end instead of using a cut mask.

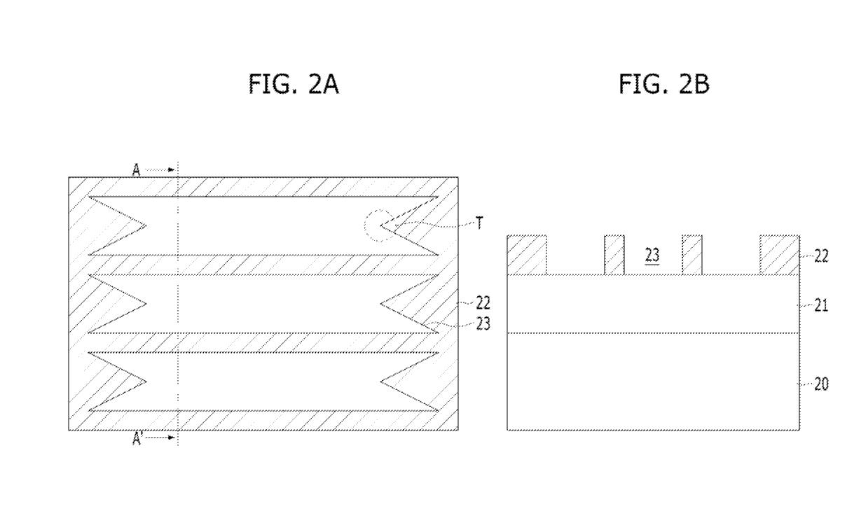

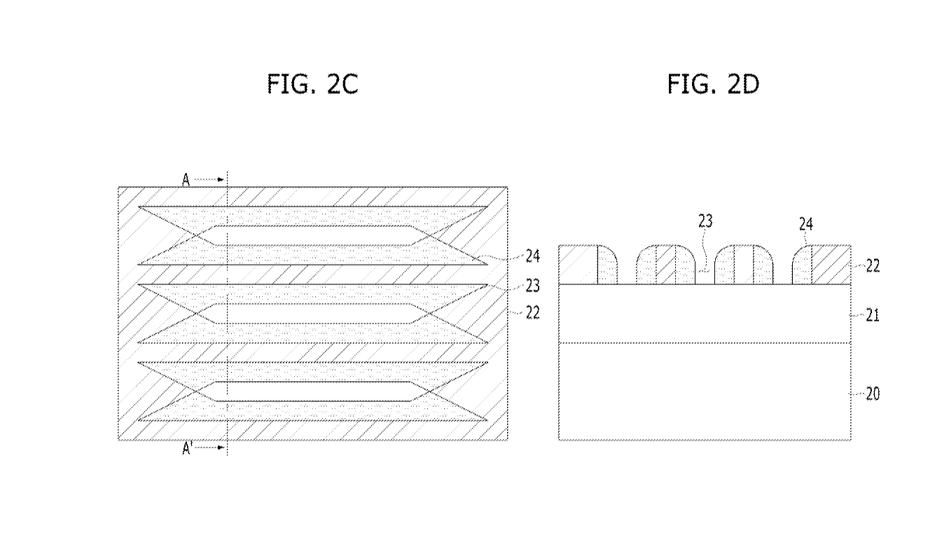

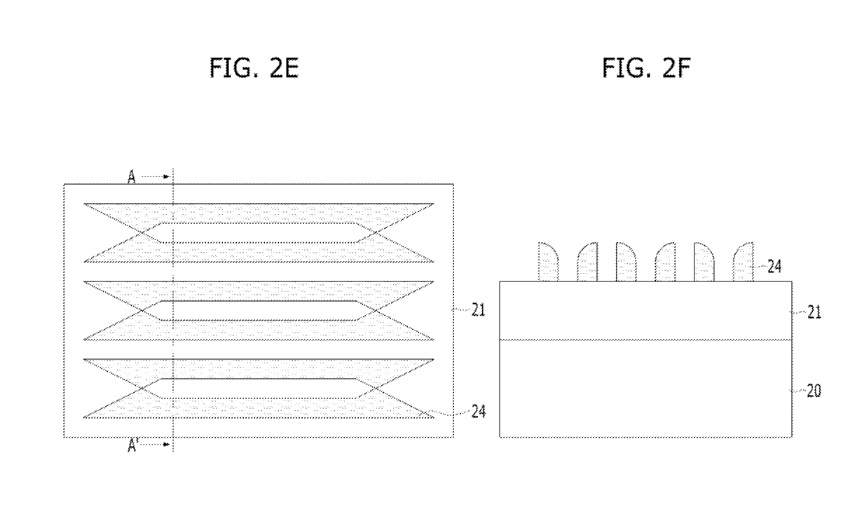

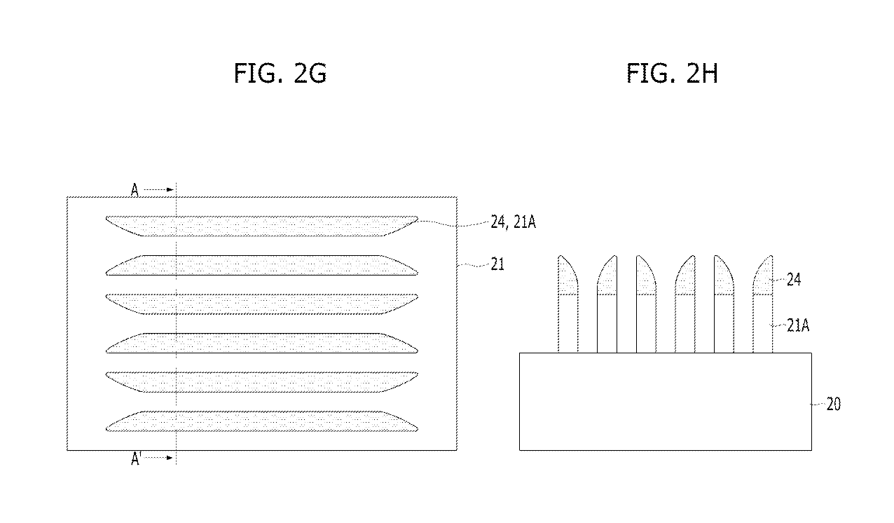

FIGS. 2A to 2H illustrate a method for forming fine line patterns in accordance with a second embodiment. FIGS. 2A, 2C, 2E and 2G are plan views, and FIGS. 2B, 2D, 2F and 2H are cross-sectional views taken along lines A-A′ of the plan views.

Referring to FIGS. 2A and 2B, an etch target layer 21 is formed over a substrate 20, and a sacrificial layer 22 is formed over the etch target layer 21. The etch target layer 21 and the sacrificial layer 22 may include various materials that are known to those skilled in the art.

Subsequently, a plurality of sacrificial patterns 23 having at least one tapered point T at each end are formed by selectively etching the sacrificial layer 22. The sacrificial patterns 23 may be intaglio patterns engraved in the sacrificial layer 22. In other words, the sacrificial patterns 23 may be formed in the sacrificial layer 22 in the form of spaces or openings that expose the etch target layer 21.

The intaglio sacrificial patterns 23 may have two tapered points which define a tapered point T at opposing ends of each sacrificial pattern that point outwards from the patterns 23. In an embodiment, sacrificial layer 22, which defines the sacrificial patterns 23, has opposing triangular protrusions defining tapered points T which point towards one another across each sacrificial space pattern 23. Put another way, the sacrificial pattern 22 includes a plurality of tapered points T disposed at opposing ends of spaces 23 in the sacrificial pattern 22, and the tapered points T of each space 23 point towards one another. Although FIG. 2A shows sacrificial patterns 23 which define a single tapered point T at each end, in other embodiments a plurality of tapered points T disposed at each far end of the patterns 23.

Referring to FIGS. 2C and 2D, spacers 24 are formed on the inner sidewalls of each of the sacrificial patterns 23. The spacers 24 may be formed of a material having an etch selectivity with respect to the etch target layer 21.

The spacers 24 may be formed through a series of processes of depositing a predetermined thickness of a material layer over the profile of a substrate structure including the sacrificial patterns 23, and then performing a blanket etch process, e.g., an etch-back process. Herein, when the material layer is formed over the profile of a substrate structure including the sacrificial patterns 23, the material layer is deposited relatively thin, or lightly deposited, at far ends of the sacrificial patterns 23 due to the presence of the tapered points T. As a result, a line width of the spacers 24 decreases as it approaches the ends of each spacer 24.

Referring to FIGS. 2E and 2F, the sacrificial layer is removed. The sacrificial layer 22 may be removed through a dry etch process or a wet etch process. When removing the layer 22, regions of the spacers 24 that are relatively protruded due to the tapered points T of the sacrificial patterns 23 may be partially removed. In other words, thin extremities of the spacers 24, such as the tapered points at far ends of the spacers 24, may be partially removed during the etching process.

Referring to FIGS. 2G and 2H, a plurality of patterns 21A are formed by using the spacers 24 as etch barriers and etching the etch target layer 21. The patterns 21A may be formed through a dry etch process. The patterns 21A may be line and space patterns, and the line width of the lines may be the same as the line width of the spaces 24.

During the etch process for forming the patterns 21A, the ends of the spacers 24 which have a relatively thin line width are etched more than the thicker central portions of the spacers 24 as a result of an etch characteristic in which thin material sections are removed more rapidly than thick material sections. As a result, the neighboring spacers 24 of each pattern 21A may be separated from each other. In addition, the shape of the spacers 24, which are the etch barriers, is transferred to the patterns 21A, and the ends of the patterns 21A may have a gradually decreasing line width. In an embodiment, the ends of the patterns 21A have the line width that gradually decreases. More specifically, as seen in FIG. 2G, an embodiment may form spacers 24 which have a first sidewall that is substantially straight, and a second sidewall opposed to the first sidewall that has a middle portion that is substantially parallel to the first sidewall and end portions that taper to meet the second first sidewall.

According to the embodiment described above with respect to FIG. 2, a plurality of fine patterns 21A are formed by forming the sacrificial patterns 23 having at least one tapered point T at each end.

Hereafter, a method for forming hole patterns is described with reference to the above described first and second embodiments.

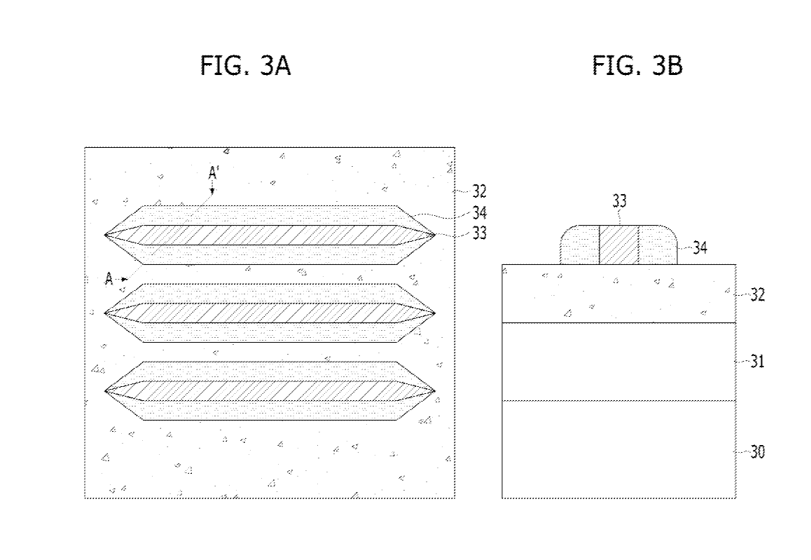

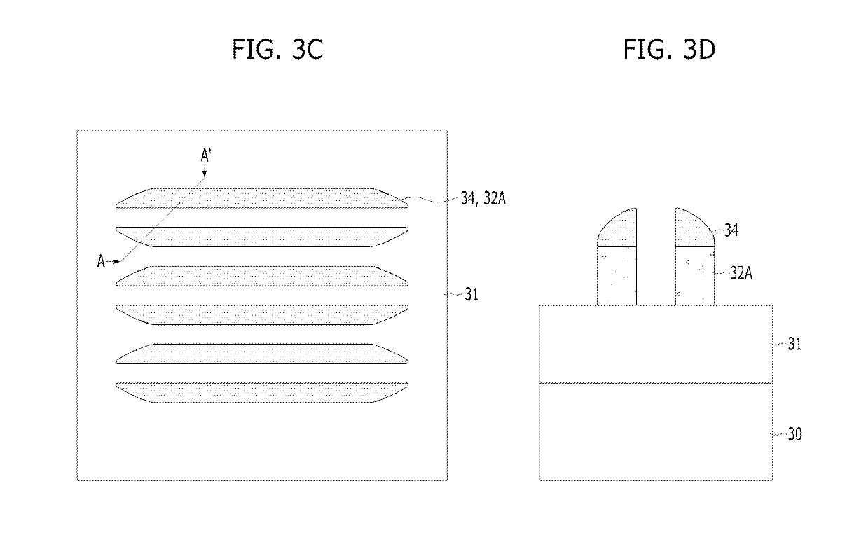

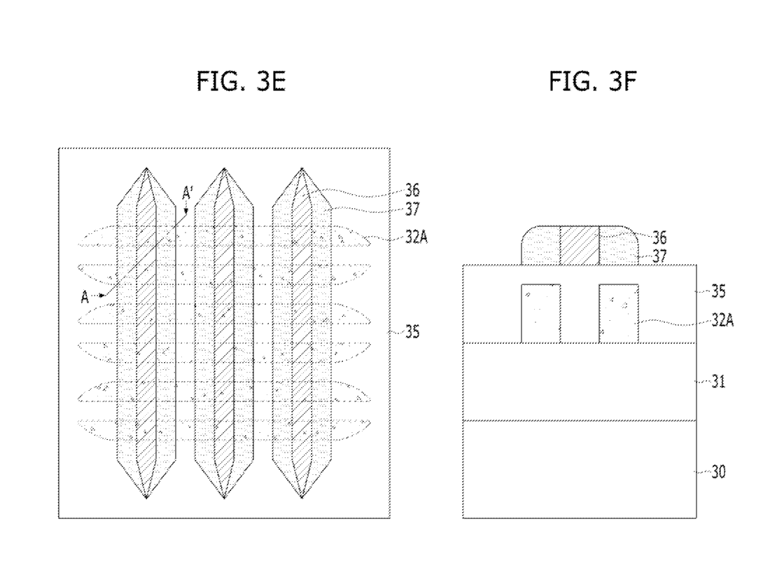

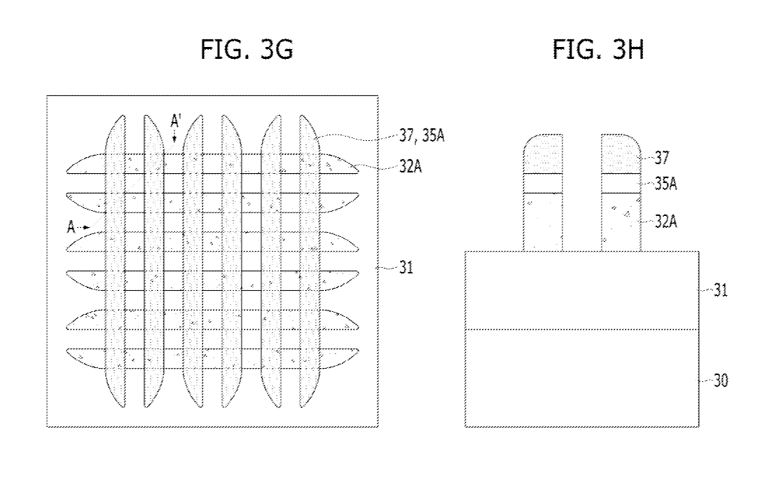

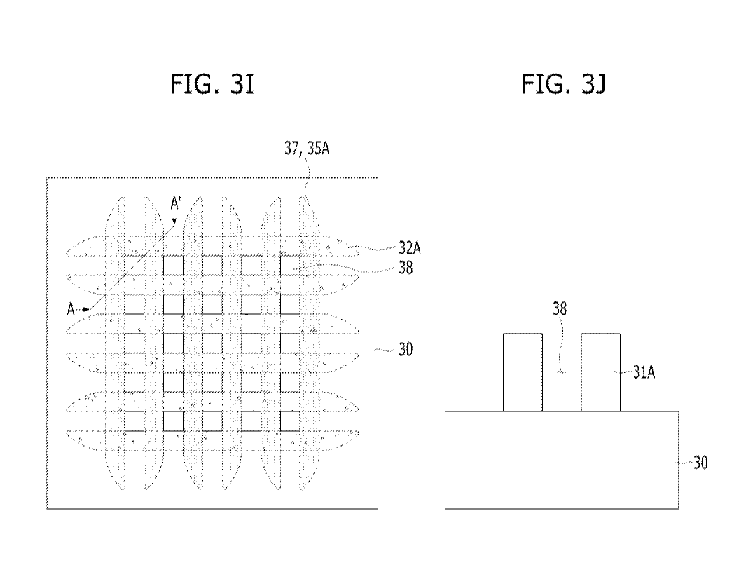

FIGS. 3A to 3J illustrate a method for forming fine hole patterns in accordance with an embodiment. FIGS. 3A, 3C, 3E, 3G and 3I are plan views, and FIGS. 3B, 3D, 3F, 3H and 3J are cross-sectional views taken along lines A-A′ of the plan views.

Referring to FIGS. 3A and 3B, a first etch target layer 31 and a second etch target layer 32 are sequentially formed over a substrate 30. Each of the first etch target layer 31 and the second etch target layer 32 may include a variety of materials that are known to those skilled in the art. The first etch target layer 31 and the second etch target layer 32 may include materials having different etch selectivities.

Subsequently, a plurality of first sacrificial patterns 33 having at least one tapered point T at each end are formed over the second etch target layer 32. The first sacrificial patterns 33 may be embossed patterns. The embossed first sacrificial patterns 33 may have the tapered points T at the ends of each first sacrificial pattern 33 that point outward from the first sacrificial patterns 33.

Subsequently, first spacers 34 are formed on the sidewalls of each of the first sacrificial patterns 33. The first spacers 34 may be formed of a material having an etch selectivity that is different from the second etch target layer 32. The first spacers 34 may have a shape in which the line width decreases as it approaches the ends. The first spacers 34 of each first sacrificial pattern 33 that are disposed adjacent to each other at the tapered points may be connected to each other in a relatively thin line width or separated from each other.

Referring to FIGS. 3C and 3D, the first sacrificial patterns 33 are removed. The first sacrificial patterns 33 may be removed through a dry etch process or a wet etch process. Herein, portions of the ends of the first spacers 34 having a relatively thin line width may be partially removed. As a result, pairs of the first spacers 34 disposed adjacent to each other may be separated from each other at each end.

Subsequently, a plurality of first patterns 32A are formed by using the first spacers 34 as etch barriers and etching the second etch target layer 32. The first patterns 32A may be formed through a dry etch process. During the etch process for forming the first patterns 32A, more material may be removed from the relatively thin ends of the spacers 34 than the relatively thick middle portions of the spacers, which is the characteristics of an etch process. As a result, the spacers 13 disposed adjacent to each other of each first pattern 32A may be separated from each other at the ends. Also, the shape of the first spacers 34, which are the etch barriers, is transferred to the first patterns 32A, and the ends of the first patterns 32A may have a gradually decreasing line width. Herein, the ends of the first patterns 32A may have a line width that gradually decreases in such a manner that one sidewall of each end angles inwards to meet the opposing sidewall.

Referring to FIGS. 3E and 3F, after the first spacers 34 are removed, a third etch target layer 35 covering the first patterns 32A is formed over the first etch target layer 31. The third etch target layer 35 may include a variety of materials that are known to those skilled in the art, and the third etch target layer 35 may include a material having an etch selectivity that is different from the first etch target layer 31 and the first patterns 32A.

Subsequently, second sacrificial patterns 36 and second spacers 37 crossing the first sacrificial patterns 33 and the first spacers 34 are formed over the third etch target layer 35 in the same method to form the first sacrificial patterns 33 and the first spacers 34 described above.

Referring to FIGS. 3G and 3H, the second sacrificial patterns 36 are removed. The second sacrificial patterns 36 may be removed through a dry etch process or a wet etch process. Herein, the ends of the second spacers 37 having a relatively thin line width may be partially removed. As a result, the second spacers 37 disposed adjacent to each other may be separated from each other at each end.

Subsequently, the third etch target layer 35 is etched using the second spacers 37 as etch barriers until the first etch target layer 31 is exposed, thereby forming third etch target patterns 35A.

The etch process may be a dry etch process. During the etch process, the ends of the second spacers 37 having a relatively thin line width are more etched. As a result, pairs of second spacers 37 disposed adjacent to each other may be separated from each other at the ends. The ends of the second spacers 37 may have a gradually decreasing line width. One sidewall of each end may be turn diagonally to meet the opposing sidewall. The shape of the second spacers 37 is transferred to the third etch target patterns 35A.

Referring to FIGS. 3I and 3J, second patterns 31A are formed by using the first patterns 32A and structures including the second spacers 37 and third etch target patterns 35A as etch barriers and etching the first etch target layer 31. Since the first patterns 32A cross the structures including second spacers 37, and third etch target patterns 35A cross each other, the second patterns 31A may be hole patterns including a plurality of holes 38. Although the crossing structures are orthogonal to one another in FIG. 3I, in other embodiments they may cross one another at an oblique angle.

Subsequently, the remaining first patterns 32A, the second spacers 37 and third etch target patterns 35A may be removed.

According to the above-described embodiments, a plurality of fine patterns each of which is divided into two pieces at the ends of each fine pattern may be formed by not using a cut mask but by forming the sacrificial patterns having at least one tapered point at each end.

The embodiment of FIG. 3A-3J has been described using the method for forming fine patterns in accordance with the first embodiment of FIG. 1A-1H, However, in other embodiments, hole patterns 31A may be formed using the method for forming fine patterns in accordance with the second embodiment of FIG. 2A-2H. In other embodiments, hole patterns may be formed through a combination of the methods for forming fine patterns in accordance with the first and second embodiments of the present invention.

According to an embodiment, fine patterns each of which is divided at the ends may be formed by forming sacrificial patterns each having at least one tapered point at the ends of each sacrificial pattern instead of using a cut mask. Accordingly, the forming process may be simplified, which leads to improved productivity.

While this disclosure describes specific embodiments, it will be apparent to those skilled in the art that various changes and modifications may be made without departing from the spirit and scope of the following claims.

What is claimed is:

1. A method for forming fine patterns, comprising:
forming a sacrificial layer over an etch target layer;
forming a plurality of sacrificial patterns each of which has at least one tapered point at first and second ends by etching the sacrificial layer;
forming spacers at sides of each of the sacrificial patterns;
removing the sacrificial layer; and
forming the fine patterns by etching the etch target layer using the spacers as etch barriers.

2. The method of claim 1, wherein the sacrificial patterns are lines or spaces.

3. The method of claim 1, wherein the sacrificial patterns are line patterns having at least one tapered point that protrudes away from the sacrificial pattern.

4. The method of claim 2, wherein each of the sacrificial patterns define at least one tapered point protruding from the sacrificial layer.

5. The method of claim 1, wherein the fine patterns have a line width that gradually decreases at the first and second ends of the fine patterns.

6. The method of claim 4, wherein each of the fine patterns has a first side and a second side opposing the first side, and end portions of the second side are angled towards the first side.

7. The method of claim 1, wherein the sacrificial patterns and the fine patterns include a plurality of line shaped patterns spaced apart from one another.

8. A method for forming fine patterns, comprising:
forming a second etch target layer over a first etch target layer;
forming a plurality of first sacrificial patterns, each of which has at least one tapered point at first and second ends, over the second etch target layer;
forming first spacers at sides of each of the first sacrificial patterns;
forming first patterns by etching the second etch target layer using the first spacers as etch barriers;
forming a plurality of second sacrificial patterns, each of which has at least one tapered point at opposing ends of each second sacrificial pattern and crosses the first sacrificial patterns over the first etch target layer;
forming second spacers at sides of each of the second sacrificial patterns; and
forming second patterns by etching the first etch target layer using the second spacers and the first patterns as etch barriers.

9. The method of claim 8, further comprising:
removing the first sacrificial patterns before the first patterns are formed;
forming a third etch target layer that covers the first patterns over the first etch target layer before the second sacrificial patterns are formed; and
removing the second sacrificial patterns before the second patterns are formed.

10. The method of claim 8, wherein the first sacrificial patterns and the second sacrificial patterns are lines or spaces.

11. The method of claim 8, wherein each of the first sacrificial patterns and the second sacrificial patterns are elongated patterns which have at least one tapered point that protrudes outwards from each respective first and second sacrificial pattern.

12. The method of claim 8, wherein each of the first sacrificial patterns and the second sacrificial patterns are spaces that define at least one tapered point which points inwards an interior of each respective first and second sacrificial pattern.

13. The method of claim 8, wherein the first sacrificial patterns and the second sacrificial patterns have a line width that gradually decreases towards opposing ends of the first sacrificial patterns and the second sacrificial patterns.

14. The method of claim 13, wherein each of the first sacrificial patterns and the second sacrificial patterns has a first side that is substantially straight, and a second side that angles inwards to meet the first side at the opposing ends.

15. The method of claim 8, wherein the first sacrificial patterns, the second sacrificial patterns and the first patterns include a plurality of line shaped patterns spaced apart from one another.

16. The method of claim 8, wherein the second patterns include hole patterns.
